(19) United States
(12) Patent Application Publication
(10) Pub. No.: US 2024/0248138 A1
(43) Pub. Date: Jul. 25, 2024

(54) Method and Apparatus for Predictive Diagnosis of a Device Battery of a Technical Device Using a Trace Graph Model

(71) Applicant: Robert Bosch GmbH, Stuttgart (DE)

(72) Inventors: Antonia Reiter, Stuttgart (DE); Christian Simonis, Leonberg (DE); Cosmin Lazar, Cluj-Napoca (RO); Daniel Asztalos-Balasy, Targu Mures (RO); Maria Belen Bescos Del Castillo, Moensheim (DE)

(21) Appl. No.: 18/393,857

(22) Filed: Dec. 22, 2023

(30) Foreign Application Priority Data
Jan. 25, 2023 (DE) 10 2023 200 585.9

(51) Int. Cl. G01R 31/367; G01R 31/382; G01R 31/392

(52) U.S. Cl. CPC G01R 31/367; G01R 31/382; G01R 31/392

(57) ABSTRACT

A monitoring method includes ascertaining from a temporal operating variable curve of operating variables of a battery an operating feature point characterizing a battery state and/or an operating history in a time period between a most recent and a second most recent change point time in the curve, providing a trace graph model comprising nodes with respective characteristic operating feature points connected via directed transitions with respective transition probabilities. One node is an anomaly node associated with an operating feature point corresponding to a particular fault of the battery. The ascertained operating feature point is assigned to one of the nodes as a monitoring node. An overall probability of occurrence of a fault is ascertained as a sum of all path probabilities from the monitoring node to the anomaly node. The path probability is a product of the respective transition probabilities along the nodes of the respective path.

This application claims priority under 35 U.S.C. § 119 to application no. DE 10 10 2023 200 585.9, filed on Jan. 25, 2023 in Germany, the disclosure of which is incorporated herein by reference in its entirety.

The disclosure relates to methods for predictive monitoring device batteries for technical devices, in particular methods for predictive diagnosis of device batteries by predictive anomaly detection.

### BACKGROUND

The supply of energy to electrical devices and machines operated independent of a network, e.g., electrically powerable motor vehicles, is normally performed by means of device batteries or vehicle batteries. The latter supply electrical energy used to operate the devices.

Device batteries degrade over their service life and according to their load or usage. Referred to as ageing, the result is a continuously decreasing maximum power or storage capacity. The ageing state corresponds to a measure used to indicate the ageing of energy storage means. Conventionally, a new device battery can have a 100% ageing state (regarding its capacity, SOH-C), which decreases more and more over the course of the battery service life. A degree of ageing of the device battery (temporal change in the ageing state) depends on an individual load on the device battery, i.e., in the case of vehicle batteries of motor vehicles, on the usage behavior of a driver, external ambient conditions and on the type of vehicle battery.

In order to monitor device batteries from a plurality of devices, operating variable data are typically continuously acquired and transmitted in block fashion to a central processing unit external to the device as operating variable curves. To evaluate the operating variable data, especially in physical or electrochemical battery models based on differential equations, the operating variable data are sampled as curves with a comparatively high temporal resolution (sampling rates) of between 1 and 100 Hz, for example, and a respective battery state is ascertained from this using a time integration method.

To evaluate the operating variable data, in particular to ascertain ageing states, an electrochemical battery model can be used, which is based on a differential equation system with a plurality of non-linear differential equations. The operating variable data enables modeling of a current battery state using a time integration method. Such electrochemical battery models are known, for example, from the publications US 2020/150,185A, WO2022017984A1, EP3919925A1, DE102020206915B3 and US20210373082A1.

In battery-powered technical devices, the proper functioning of the device battery used must be regularly monitored for faults for safety reasons, especially at high energy densities. If one battery cell, a unit consisting of multiple battery cells or the entire device battery fails, the technical device can become inoperable, depending on the fault that has occurred and, under some circumstances, the safety of the technical device and of the user can be compromised in the event of malfunctions leading to a severe temperature increase.

However, due to rule-based anomaly detection, faults in device batteries have so far only been detected when applied fault threshold values for operating variables, such as the cell voltage, a module temperature, a current value or a state of charge value and an ageing state value, are exceeded or not reached.

Publication DE 10 2019 208 372 A1 discloses an exemplary computer-implemented method for detecting an anomaly in a technical system, with the following steps: Acquisition of an operating variable vector which indicates an operating state of the technical system and comprises a number of operating state variables, wherein the operating state variables comprise at least one ambient state variable which indicates an ambient condition in which the technical system is operated, and system state variables indicating internal system states of the technical system; providing an ambient state model and an anomaly detection model, wherein the ambient state model indicates a verifiability of the operating variable vector with respect to the presence of an anomaly using the anomaly detection model, depending on at least one of the ambient state variables, and wherein the anomaly detection model indicates the presence of an expected anomaly dependent on the operating variable vector, signaling a presence of an anomaly or a non-anomaly dependent on an evaluation of the at least one ambient state variable of the operating variable vector using the ambient state model and dependent on an evaluation of the operating variable vector dependent on the anomaly detection model.

### SUMMARY

According to the present disclosure, there is provided a method for monitoring a device battery of a technical device having one or more battery cells according to the disclosure as well as an apparatus and a battery system according to the disclosure.

Further embodiments are specified in the disclosure.

According to a first aspect, a method for monitoring a device battery in a technical device is provided, comprising the following steps:
provision of a temporal operating variable curve of several operating variables of a specific device battery;
ascertaining from the temporal operating variable curve at least one operating feature point which characterizes a battery state and/or an operating history in a time period between a most recent and a second most recent change point time in the temporal operating variable curve;
evaluating a provided trace graph model comprising nodes each having a characteristic operating feature point connected via directed transitions each having a transition probability, at least one of the nodes corresponding to an anomaly node associated with an operating feature point indicative of a particular fault of the device battery;
assigning the ascertained operating feature point to one of the nodes of the trace graph model as a monitoring node;
ascertaining an overall probability of occurrence of the determined fault as a sum of all path probabilities of all possible paths through the trace graph model from the monitoring node to the anomaly node, wherein the path probability is given by a product of the transition probabilities along the nodes of the respective path;
detection and signaling of a current fault or the occurrence of an imminent fault depending on the overall probability.

While the autoencoder-based approaches commonly used for anomaly detection are able to classify a current battery state as normal or anomalous, a reliable prediction of when a failure event is going to occur in the future is not possible. However, it has been observed that safety-critical events, such as a thermal runaway event or a total failure of the device battery (sudden death), are announced in advance by developments in the internal battery states, so that in principle it is possible to predict such critical events on this basis.

The above method based on a trace graph model for predictive detection of an anomaly in a device battery, i.e., a future fault occurring in the device battery, is provided in a device-external central unit which is in communication with a plurality of device batteries of technical devices in order to evaluate their operating variable curves.

For capacity reasons, the internal battery state of the device batteries of a plurality of devices is ascertained in a central processing unit external to the device. For this purpose, the devices transmit temporal operating variable curves of the device batteries in the form of time series of operating variables, such as battery current, battery temperature, charge state and/or battery voltage, to the central processing unit, wherein a current electrochemical internal battery state and/or ageing state is ascertained in the central processing unit. By evaluating the operating variable curves, a device-specific internal battery state and, if necessary, other variables, such as an ageing state, can be calculated/ascertained based on the electrochemical battery model provided for the corresponding battery type of the device battery. The evaluation can be based on the entire device battery, on individual battery cells or units/modules consisting of multiple battery cells.

To evaluate the operating variable curves, one or more battery models, each formed with a differential equation system, can be evaluated using a time integration method in order to obtain an ageing state and/or one or more battery states. Furthermore, one or more model parameters of a battery model can be fitted based on the operating variable curves, which can also indicate a battery state. Furthermore, the temporal operating variable curves can be aggregated into operating features as statistical or accumulated variables in order to characterize the cyclical load on the device battery.

For example, an ageing state model can be used to ascertain the ageing state of the device battery based on the operating variable curves.

In the case of device batteries, the ageing state (state of health, SOH) is the key variable to indicate a remaining battery capacity or remaining battery charge. The ageing state represents a measure of the ageing of the device battery. In the case of a device battery or a battery module or a battery cell, the ageing state can be indicated as a capacity retention ratio (SOH-C). The capacity retention ratio SOH-C, i.e., the capacity-based ageing state, is indicated as the ratio of the measured instantaneous capacity relative to an initial capacity of the fully-charged battery, and decreases with increased ageing. Alternatively, the ageing state can be indicated as an increase in internal resistance (SOH-R) relative to an internal resistance at the start of the service life of the device battery. The relative change in the internal resistance SOH-R increases with increasing ageing of the battery.

An ageing state model can be evaluated in the central processing unit to ascertain an ageing state for an individual device battery. For example, the current ageing state can be ascertained using a physical ageing model, which is a form of the electrochemical battery model. The physical ageing model corresponds to a system of differential equations and is evaluated using a time integration method. This differential equation system can be parameterized by operating variable curves of a large number of device batteries of the same type.

Such a physical ageing state model is inaccurate in certain situations and usually exhibits model deviations of up to more than 5%, especially in the calibration-free case, such as in a prediction where no real quiescent stress can be measured for model adjustment. Due to the inaccuracy of the physical ageing model, it can moreover only somewhat accurately indicate the instantaneous ageing state of the device battery.

To improve the accuracy of the ageing state model, it can be provided in the form of a hybrid ageing state model, a combination of the physical ageing model and a data-based correction model. In a hybrid ageing state model, a physical ageing state can be ascertained using the physical or electrochemical ageing model and a correction value can be applied to it, which results from the data-based correction model, in particular by addition or multiplication. As described above, the physical ageing model is based on electrochemical model equations that characterize electrochemical states of a non-linear differential equation system, calculate them continuously and map them to the physical ageing state as SOH-C and/or SOH-R for output. The calculations can typically be performed in the cloud, e.g., once a week.

Furthermore, the correction model of the hybrid data-based ageing state model can be designed with a probabilistic or artificial intelligence-based regression model, in particular a Gaussian process model, and can be trained to correct the ageing state obtained by the physical ageing model. For this purpose, there are consequently a data-based correction model of the ageing state for correcting the SOH-C and/or at least one further model for correcting the SOH-R. Possible alternatives to the Gaussian process are further supervised learning methods, such as those based on a random forest model, an AdaBoost model, a support vector machine, or a Bayesian neural network.

The correction model can use operating features as input variables, which have been determined from the operating variable curves using feature extraction or feature extraction methods, wherein the features are calculated using signal processing operations. The operating features assigned to an operating variable curve define an operating feature point for the energy storage system in question, which maps the load state due to cyclical operation (cyclical ageing) and the calendar ageing of the energy storage system (elapsed period of time since commissioning or start of service life).

The operating features can comprise cumulative load-based features or aggregated features and/or statistical variables ascertained over the entire service life to date. In particular, features from histogram data that were created from the curves of the operating variables can be ascertained as operating features. For example, histograms with respect to the battery current over the battery temperature and the charging state of the vehicle battery, a histogram of the battery temperature over the charging state of the vehicle battery, a histogram of the charging current over a battery temperature, and a histogram of a discharging current over the battery temperature can be created. Furthermore, the accumulated total charge (Ah), an average capacity increase during a charging process (in particular for charging processes in which the charge increase is above a threshold fraction [e.g., 20% ΔSOC] of the total battery capacity), the charging capacity as well as an extreme value (e.g., a local maximum) of the smoothed differential capacity during a measured charging process with sufficiently large stroke of the charging state (smoothed curve of dQ/dU: charge change divided by change in the battery voltage) or the accumulated driving power, respectively since the initial operation of the device battery, can be taken into account as operating features. Further operating features can correspond to a local extreme value of the spectral kurtosis, evaluated on a charging process for current or voltage signal, one or more coefficients of a wavelet transform and/or one or more coefficients of the Fourier transform, each evaluated for a charging process for a current or voltage signal or a transformed spectral value assigned to a defined frequency band.

Operating features can thus be derived from histograms with regard to operating variables. From this, feature engineering or feature extraction methods can be used to extract operating features such as the mean value, the standard deviations of the histograms and multidimensional statistical values such as mean value, median, minimum, maximum, moments of the distribution and the like.

Internal battery states can be ascertained using an electrochemical battery model. The electrochemical battery model comprises a differential equation system which, based on differential equations parameterized via model parameters, models internal battery states, in particular equilibrium states and, if applicable, kinetic states, using a time integration method and provides a relationship between operating variables of the battery cells of the device battery, namely a battery current, a battery voltage, a battery temperature and a state of charge of the device battery. The electrochemical battery model can be evaluated in the external central processing unit or in a control device for an individual device battery in order to determine the internal battery states. Such electrochemical battery models are known, for example, from the publications US 2020/150,185A, WO2022017984A1, EP3919925A1, DE102020206915B3 and US20210373082A1.

Model parameters of the electrochemical battery model can be fitted or parameterized (adaptation of the model parameters by minimizing the fault squares) in the central processing unit based on operating variable curves of a plurality of device batteries of the same type within a limited period of time acquired during idle phases (a few minutes to a few hours), wherein electrochemical, equilibrium parameters and/or kinetic model parameters can be derived, which can comprise, for example, electrolyte concentrations, response rates, layer thicknesses, porosity, etc. The parameterization can be based on a highly accurate measurement of the ageing state of the device batteries using known methods.

Furthermore, a battery performance model based on the operating variable curves can be evaluated in the central processing unit in order to provide equivalent circuit diagram parameters, such as internal resistances and a capacity of a battery equivalent circuit diagram.

Furthermore, the one or more derived variables can comprise one or more operating features derived from the operating variable curves and/or an ageing state derived from the operating variable curves and/or one or more internal battery states derived from the operating variable curves and/or one or more model parameters of a battery model fitted to the operating variable curves.

Based on the operating variable curves provided, which are provided as time series of the battery current, the battery voltage, the state of charge and the battery temperature, on an ageing state derived therefrom using the ageing state model, on one or more internal battery states ascertained from the electrochemical ageing model as a result of the evaluation by the differential equation system as well as the operating features that have already been ascertained for the correction model using a feature extraction block and which are derived from the operating variable curves as aggregated variables, such as histogram-based signals, an anomaly prediction model is trained or evaluated.

The above method is based on a trace graph model (trace graph) that has been created based on the operating feature points of a large number of proper or abnormal, faulty, device batteries. The operating feature points correspond to a combination of a battery state and an operating history of the device battery and are determined by a combination of one or more operating variables, one or more operating features, one or more battery states and/or an ageing state with reference to a specific time or to a specific time period of the operating variable curves. The operating feature points therefore represent a characteristic indication of the state of the device battery and its operating history for the specific point in time.

The trace graph comprises nodes, each of which is assigned an operating feature point that indicates a state of the device battery at the end of a characteristic time period of operating variable curves. The nodes are connected as start nodes via edges as directed transitions with one or more further nodes (end nodes). The transitions indicate the chronological sequence of the characteristic time periods assigned to the nodes. A transition runs from a start node to an end node. Each of the transitions is assigned a probability according to which a further time period of an end node follows on from a time period of the start node.

Such a trace graph is created by analyzing the operating variable curves of a plurality of device batteries to determine change point times as points in time, in particular using a Jenks Natural Breaks algorithm, at which a characteristic curve of operating variables changes. By determining the change point times in the operating variable curves, the time periods of different durations can be defined, to each of which a node is assigned in the trace graph model.

The nodes contain a compact representation of the time periods of the operating variable curves and are determined by the operating feature point at the point in time (change point time) of the respective time period. The operating feature point also comprises the duration of the time period represented by it. Furthermore, each of these time periods is assigned an indication that refers to the subsequent time period of operating variable curves of the relevant device battery.

To create the trace graph model, the operating feature points can be grouped or clustered using a suitable method, for example using a clustering method known per se based on a similarity measure or distance measure, such as a Euclidean distance, in order to group those operating feature points that are assigned to comparable battery states and a comparable operating history and assign them to the same node in the trace graph model.

At the same time, the ascertaining of the operating feature points for the time periods of the operating variable curves and the evaluation of the time series of the time periods of the entire operating variable curves results in a frequency distribution of the transitions from a node that represents a time period of the assigned operating variable curves to a subsequent node of the trace graph model that represents a subsequent time period of the assigned operating variable curves. In other words, each operating feature point is assigned a subsequent operating feature point by evaluating the operating variable curves of successive time periods of the same device battery. By evaluating the frequencies of the subsequent operating feature points of operating feature points assigned to a specific node, probabilities of a transition from a start node of the trace graph model can be determined. These transition probabilities indicate the probabilities with which a time period of an operating variable curve that is assigned to a specific start node is followed by a time period with an operating variable curve that leads to an operating feature point or is represented by it and that is assigned to a corresponding end node. The start node and end node can also be identical.

By evaluating a large number of device batteries, various operating feature points, each represented by a node, can be determined. This also includes operating feature points that can be assigned to abnormal battery behavior or a critical fault in the device battery. Creating the trace graph model also results in corresponding transition probabilities for the nodes that characterize anomalous battery states.

Thus, the trace graph can be analyzed to determine a probability of failure due to a battery fault associated with a particular node and a time duration until the probable failure of the device battery due to the occurrence of the particular battery fault. For this purpose, an operating feature point for the device battery to be monitored can be generated as described above by evaluating a corresponding time period of operating variable curves at a current point in time or at a determined change point time.

The assigning of the ascertained operating feature point can be performed to one of the nodes as a monitoring node according to a similarity measure indicating the greatest similarity between the operating feature point assigned to the monitoring node and the ascertained operating feature point, wherein the similarity measure indicates a Euclidean distance between the operating feature points.

This operating feature point is thus assigned to the monitoring node of the trace graph model whose assigned operating feature points are most similar to the specific operating feature point. A similarity measure or distance measure can be used for the assignment, which is determined, for example, by a Euclidean distance of the operating feature point from a centroid of the operating feature points assigned to the node to be assigned.

The node that represents the operating feature points of device batteries for which the particular fault has occurred is called the anomaly node. All paths that lead from the monitoring node to the anomaly node can now be determined by the trace graph model. For these paths, an overall probability can be determined as the sum of the probabilities of all possible paths (path probability), which indicates the probability with which the current operation of the monitored device battery leads to the specific fault. The path probabilities are the product of the transition probabilities between all nodes of the path under consideration between the monitoring node and the anomaly node.

It may be provided that each operating feature point is assigned a time duration of the assigned time period of the operating variable curve, wherein an average time duration until the occurrence of the determined fault is ascertained as the mean value of the path probability weighted sum of the time durations of the operating feature points of all nodes along a path over all possible paths between the monitoring node and the anomaly node.

The point in time of occurrence of the specific error, starting from the current point in time, results from the mean value of the total durations weighted with the path probabilities (sum of the durations assigned to the centroids of the node in each case) of the nodes along the respective path through the trace graph model.

If the fault is detected, a warning or recommendation can be issued to a user of the technical device or the operation of the device battery can be adjusted. Depending on the overall probability of a battery state being reached at a point in time at which the specific device battery fault occurs or is present, a corresponding warning or recommendation can be signaled to the user of the technical device or operation of the technical device can be controlled in such a way that the battery state can be avoided as far as possible.

Since the elements of the operating feature points can be physically interpreted and in particular comprise internal battery states from an electrochemical battery model and/or operating features derived from operating variable curves, measures can be derived by looking at the differences between the values of the corresponding operating features of the current operating feature point and the operating feature point of the anomaly node, which prevent a transition to the corresponding anomaly node. These measures may comprise, for example, intervention in the operation of the device battery or corresponding recommendations to the user of the technical device. An intervention in the operation of the device battery can be achieved, for example, by providing an additional limitation of operating variables, such as a temperature limitation, a limitation of a current throughput, a limitation of the frequency of fast charging processes and the like. In this way, the stress exerted on the device battery by stress factors can be reduced in advance so that the electrochemical internal battery states of the battery cells (SEI thickness, cyclizable lithium, . . . ) can remain in a normal state. Anomalies can thus be effectively suppressed by limiting at least one load or operating variable on the basis of trace graph prediction.

According to a further aspect, a method for creating a trace graph model for monitoring device batteries of technical devices is provided, wherein the trace graph comprises nodes each having a characteristic operating feature point, which are connected via directed transitions each having a transition probability, wherein at least one of the nodes corresponds to an anomaly node to which an operating feature point corresponding to a certain fault of device batteries is assigned, comprising the following steps:
providing a wide range of operating variable curves for a large number of device batteries;
determination of time periods of the operating variable curves using a determination of change point times separating the time periods within each of the operating variable curves;
ascertaining an operating feature point for each of the time periods;
assigning the operating feature points to clusters, each of which is assigned to a node of the trace graph model;
determination of directed transitions between the nodes of the trace graph model, which are each provided with a transition probability from one node to a further node, the transition probabilities being determined in each case from an evaluation of frequencies of the transition of a state of the device battery determined by a respective one of the nodes to a respective further state of the device battery determined by a respective one of the nodes.

The trace graph is preferably created by evaluating operating variable curves of a large number of technical devices and the corresponding graph model parameters, e.g., the centroids of the operating feature points assigned to a node and the transition probabilities of the transitions departing from the respective node, are transferred to the individual technical devices so that the method can also be executed embedded in the technical devices. This means that predictive anomaly detections can be carried out in the technical devices even without a communication connection to the central unit external to the device.

### BRIEF DESCRIPTION OF THE DRAWINGS

Embodiments are explained in more detail in the following with reference to the accompanying drawings. Here:

FIG. 1 shows a schematic representation of a system for providing driver- and vehicle-specific operating variables for detecting a predicted anomaly of a vehicle battery in a central processing unit;

FIG. 2 a flowchart illustrating a method for using a trace graph model in a vehicle;

FIG. 3 a schematic representation of a trace graph model with exemplary transition probabilities; and

FIG. 4 a flowchart illustrating a method for creating a trace graph model using operating variable curves of a large number of vehicle batteries.

### DETAILED DESCRIPTION

In the following, the method according to the disclosure is described using vehicle batteries as device batteries in a plurality of motor vehicles as similar devices. For this purpose, one or more electrochemical battery models are evaluated and parameterized in the central processing unit based on operating variable curves. In the central unit, a trace graph is modeled by evaluating the operating variable curves and the model parameters of the trace graph model are transferred to the control units of the vehicles in the vehicle fleet so that an anomaly can be detected there by continuously monitoring the vehicle battery using the trace graph model.

The above example is representative of a plurality of stationary or mobile devices with a network-independent energy supply, such as vehicles (electric vehicles, pedelecs, etc.), systems, machine tools, household appliances, IOT devices, and the like, which are connected via a corresponding communication connection (e.g., LAN, Internet) to an external central processing unit (cloud).

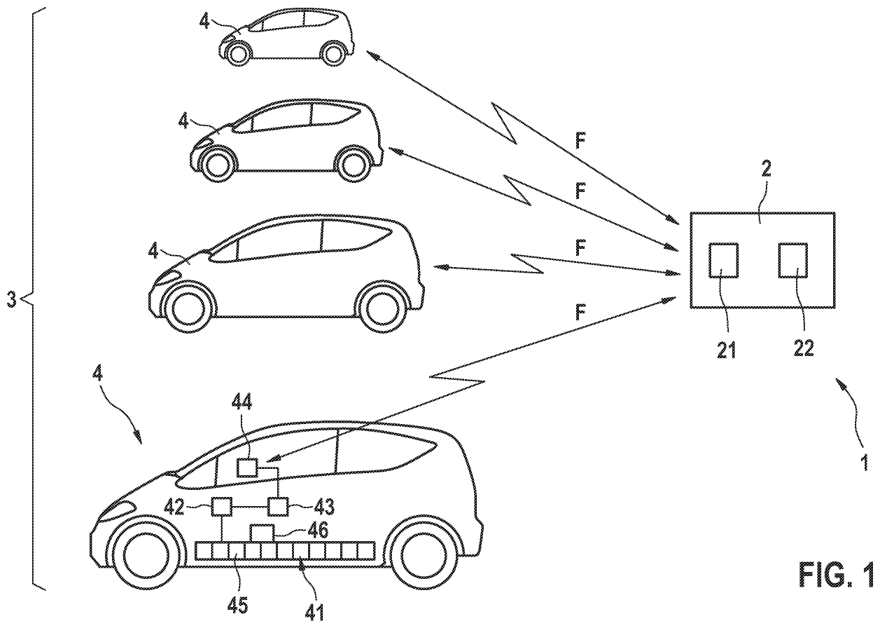

FIG. 1 shows a system 1 for collecting fleet data in a central processing unit 2 for creating, operating and evaluating an electrochemical battery model and a battery performance model, each for modeling internal battery states of the vehicle battery and an ageing state model for determining the ageing state of a vehicle battery in a motor vehicle.

FIG. 1 shows a vehicle fleet 3 with several motor vehicles 4. One of the motor vehicles 4 is shown in greater detail in FIG. 1. The motor vehicles 4 each have a vehicle battery 41 with battery cells 45, an electric drive motor 42 and a control unit 43. The control unit 43 is connected to a communication device 44, which is suitable for transmitting data between the respective motor vehicle 4 and a central processing unit 2 (a so-called cloud).

In particular, the control unit 43 is designed to use a battery management system 46 to acquire operating variables of the vehicle battery 41 with a high temporal resolution, such as between 1 and 50 Hz, e.g., 10 Hz, and to transmit these to the central processing unit 2 via the communication device 44.

The motor vehicles 4 transmit to the central processing unit 2 the operating variables F, which at least indicate variables that influence the ageing state of the vehicle battery 41 or are influenced by it, and which are required for determining the internal battery states, an ageing state, a parameterization of an electrochemical battery model. In the case of a vehicle battery, the operating variables F can indicate an instantaneous battery current, an instantaneous battery voltage, an instantaneous battery temperature and an instantaneous state of charge (SOC), at the pack, module and/or cell level. The operating variables F are acquired in a fast chronological grid from 0.1 Hz to 50 Hz as operating variable curves, and can be transmitted regularly to the central processing unit 2 in uncompressed and/or compressed form. For example, by using compression algorithms, the chronological series can be transmitted to the central processing unit 2 in blocks at intervals of 10 min to several hours in order to minimize data traffic to the central processing unit 2.

The central processing unit 2 has a data processing unit 21, in which part of the method described below can be carried out, and a database 22 for storing data points, model parameters, states and the like.

The central processing unit 2 is designed to receive the operating variable curves. The central unit 2 can determine a current ageing state, e.g., using an ageing state model, internal battery states, e.g., using an electrochemical battery model and/or as model parameters of a battery performance model and/or one or more operating features from the operating variable curves for the respective vehicle battery 41 in a manner known per se.

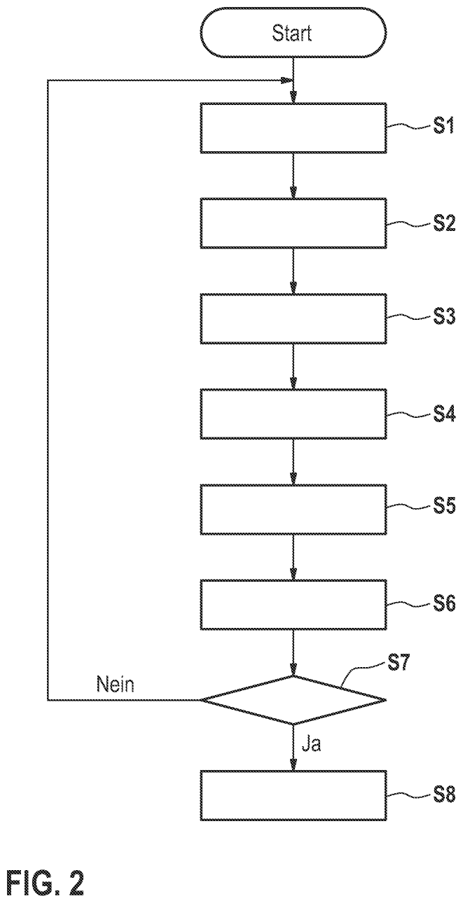

FIG. 2 uses a flowchart to illustrate the method for operating a vehicle, in particular with regard to the predictive detection of an anomaly in the vehicle battery 41 to be monitored. The method is implemented in the control unit 43 in the form of hardware and/or software.

In step S1, the operating variable data of the vehicle battery 41 to be monitored is recorded, cleaned, filtered and an outlier detection is carried out. The operating variable data for batteries generally comprises battery voltage, battery current, battery temperature and state of charge.

In step S2, the operating variable curves are segmented into time periods. The time periods result from the ascertaining of change point times based on the operating variable curves.

The operating variable curves can be analyzed using a Jenks Natural Breaks algorithm (Jenks, George F. 1967. “The Data Model Concept in Statistical Mapping”, International Yearbook of Cartography 7: 186-190), for example, in order to obtain change point times as points in time of a change in the characteristic signal curve. Separated by the detected change point times, contiguous time periods of variable duration of operating variable curves are thus obtained, in which a characteristic operation of the vehicle battery 41 is present.

The aim is to ascertain a time period of the operating variable curves up to the most recent change point found. In step S3, this time period is evaluated in the manner described above, one or more operating features derived from the operating variable curves, one or more internal battery states derived from the operating variable curves using one or more battery models and/or an ageing state are ascertained. An operating feature point is assigned to the time period, which comprises one or more of the operating features and/or one or more of the battery states and/or one or more of the operating variables averaged over the time period and also comprises a time duration of the relevant time period.

The operating features can represent aggregated and/or statistical variables derived from the operating variable curves. In particular, the spectral kurtosis of the operating variable curves, the coefficients of a wavelet transformation for certain operating states, such as during a rest phase, an extreme value of the quotient dQ/dU of a charge difference and a voltage difference during a charging process, a drop in the voltage signal during regular operation or for defined load patterns and the like can be considered as operating features.

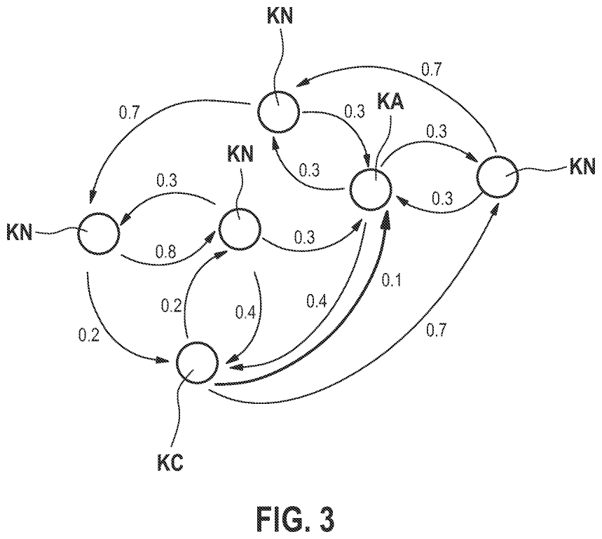

In step S4, a trace graph model is provided that contains nodes and directed transitions between the nodes. Such a trace graph model is shown in FIG. 3. The nodes are each assigned to a representative operating feature point, and the directed transitions between the nodes are weighted using probabilities. The probabilities indicate the transition probabilities with which a time period characterized by an operating feature point that is assigned to a start node is followed by a time period that is assigned to the end node. The transition probability can therefore be used to detect the probability with which the operating state defined by an operating feature point (start node) changes to an operating state defined by another operating feature point (end node).

The nodes can also comprise anomaly nodes that characterize an operating state for which there is a failure or fault in the vehicle battery 41. Starting from a node that characterizes a current operating state of the vehicle battery, the probabilities of all paths of transition probabilities to the anomaly node can now be ascertained in order to determine the probability with which a failure of the vehicle battery 41 will occur. The duration after which the vehicle battery will fail with the corresponding probability is calculated from the mean value of the durations along the paths under consideration.

FIG. 3 shows an example of a trace graph model. You can recognize the directional arrows as transitions from one node to another node with the corresponding transition probability, which are shown as an example in FIG. 3. Furthermore, the normal operating states are identified as nodes KN, the abnormal operating states as anomaly nodes KA and the monitoring node of the current operating state as KC. A complete trace graph model has a sum of 1 as the sum of all transition probabilities of incoming transitions and a sum of 1 as the sum of all outgoing transitions.

The overall probability of a transition from a first node to any second node corresponds to the sum of the path probabilities over all possible paths from the first node to the second node. For each node, the path probability along a single path is the product of the transition probabilities of the transitions between all nodes KN along the corresponding path. Thus, with knowledge of the current node KC and knowledge of an anomaly node, the overall probability can be determined with which, starting from the current node, i.e., starting from the current battery state determined by the operating feature point, a battery state is reached that corresponds to the determined fault of the anomaly node.

The mean value of the sum of the time durations of all nodes along all paths weighted with the path probabilities then indicates the average time duration after which the anomaly or the specific error occurs.

The current operating feature point determined in step S3 is assigned in step S5 to one of the nodes of the trace graph model, which represents the monitoring node. The assignment is made to the node of the trace graph model to whose assigned operating feature point the current operating feature point has the greatest similarity. The similarity of the current operating feature point to the node operating feature point can be determined by a Euclidean distance.

Now, in step S6, as described above, the overall transition probability to a selected anomaly node representing a particular fault of the vehicle battery 41 is determined and the corresponding average time duration is ascertained after which this anomaly node, at which a faulty battery state is present, is reached, starting from the battery state of the monitoring node.

If it is determined in step S7 that the transition probability is above a predetermined threshold value (alternative. Yes), a warning can be signaled to the user of the vehicle in step S8. Alternatively, the operation of the vehicle can be restricted accordingly.

In particular, a recommendation can be issued to the user to change the use of the vehicle battery 41 in order to delay the failure of the vehicle battery. For example, a recommendation system can be provided that is based on the differences between the operating features of the operating feature point of the anomaly node and the current operating feature point of the relevant vehicle battery to be monitored. The recommendation system can be rule-based, so that a corresponding recommendation can be issued depending on the differences between the operating features or operating states of the operating feature points. For example, upon detecting an overall transition probability above a predetermined threshold value, such as 80%, and an average time of occurrence of the particular fault of the vehicle battery of less than another predetermined threshold value, such as five years, a recommendation may be issued to reduce the frequency of fast charges, for example to one fast charge per week, thereby reducing the probability of the particular fault of the device battery occurring to less than 10%.

The above method can be carried out in the vehicle or in the central unit 2. For in-vehicle versions, the model parameters of the trace graph model can be updated regularly from the central unit 2.

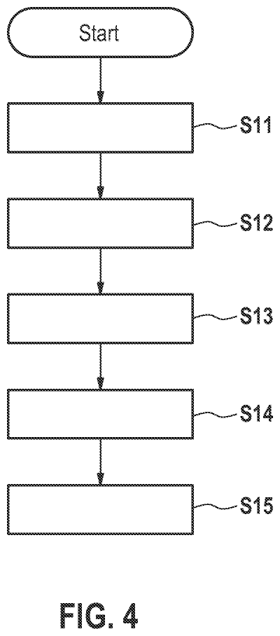

FIG. 4 shows a flow chart illustrating a method for creating a trace graph model in the central processing unit 2.

Here, a trace graph is created based on the operating variable curves F of a vehicle fleet 3.

For this purpose, the operating variable curves of a plurality of vehicle batteries 41 are received in step S11.

In step S12, the operating variable curves are analyzed accordingly and divided into time periods. The time periods are separated from each other by detected change point times. Change point times indicate points in time at which a characteristic curve of the operating variable curves changes and can be detected, for example, by a Jenks natural breaks algorithm in time series or by other methods for ascertaining change points in time series, e.g., by using clustering methods.

Once the time periods have been identified, operating feature points are assigned to these time periods in step S13 in the manner described above. As described above, the operating feature points comprise operating features that are derived as aggregated or statistical variables from the operating variable curves, battery states that are ascertained from an evaluation of the operating variable curves in electrochemical battery models, an ageing state and/or one or more operating variables aggregated over the time period (mean value, median or similar). The operating features, the battery states, the ageing state and the aggregated operating variables are ascertained separately for each of the time periods, in particular based on the operating variable curves that are taken into account up to the point in time of the end of the relevant time period. Furthermore, the corresponding durations of the time periods that characterize them are added to the operating feature points.

The operating feature points are now summarized in step S14 using suitable grouping or clustering methods. Similar operating feature vectors are recorded in a respective cluster and a node of the trace graph model is assigned to this cluster. The centroid of this grouping or cluster is the operating feature point that represents the node in question. This means that all time periods are assigned a corresponding node in the trace graph model.

Now, in step S15, the operating variable curves of each of the vehicle batteries are analyzed chronologically and the transition probabilities from a start node to an end node are ascertained in each case. The transition probabilities result from a normalization of the frequencies of all transitions (edges) departing from a start node over the operating parameter curves of all vehicle batteries under consideration 41. The frequencies are ascertained by evaluating pairs of operating feature points of all vehicle batteries 41. The pairs of operating feature points each result from the operating feature points (first operating feature point) and an operating feature point of one for the respective vehicle battery under consideration, which is determined for an immediately following time period (second operating feature point). The pairs of operating feature points are each assigned to a start node via the first operating feature points. The assignments of the second operating feature points of the pairs of a specific start node to the respective end nodes result in the corresponding frequencies for the transitions. These frequencies are converted into transition probabilities based on the total number of transitions from a start node to an end node and assigned to the arrows between the nodes of the trace graph model.

What is claimed is:

1. A computer-implemented method for monitoring a device battery in a technical device, comprising:
providing a temporal operating variable curve of several operating variables of a specific device battery;
ascertaining from the temporal operating variable curve at least one operating feature point which characterizes a battery state and/or an operating history in a time period between a most recent and a second most recent change point time in the temporal operating variable curve;
providing a trace graph model comprising nodes each having a respective characteristic operating feature point connected via directed transitions, each having a respective transition probability, wherein at least one of the nodes corresponds to an anomaly node associated with an operating feature point corresponding to a particular fault of the device battery;
assigning the ascertained operating feature point to one of the nodes of the trace graph model as a monitoring node;
ascertaining an overall probability of occurrence of a determined fault as a sum of all path probabilities of all possible paths through the trace graph model from the monitoring node to the anomaly node, wherein the path probability is given by a product of the respective transition probabilities along the nodes of the respective path; and
detecting and signaling the determined fault based upon on the overall probability.

2. The method according to claim 1, wherein the change point times are ascertained using a Jenks natural breaks algorithm or clustering method.

3. The method according to claim 2, wherein:
assigning the ascertained operating feature point to one of the nodes as a monitoring node is performed according to a similarity measure indicating a greatest similarity between the operating feature point assigned to the monitoring node and the ascertained operating feature point; and
the similarity measure indicates a Euclidean distance between the operating feature points.

4. The method according to claim 1, wherein a warning or a recommendation is issued to a user of the technical device or the operation of the device battery is adjusted when the determined fault is detected.

5. The method according to claim 4, wherein the operation of the device battery is adapted by limiting at least one load or operating variable when the determined fault is detected by the evaluation of the trace graph model to reduce a stress of one or more stress factors on the device battery.

6. The method according to claim 1, wherein:
each operating feature point is assigned a time segment of the time period of the operating variable curve; and
an average time duration until the occurrence of the determined fault is ascertained as the mean value of the sum, weighted with the path probability, of the time durations of the operating feature points of all nodes along a path over all possible paths between the monitoring node and the anomaly node.

7. The method according to claim 1, wherein the operating feature points comprise an ageing state derived from the temporal operating variable curve up to an end of the relevant time period and/or one or more internal battery states derived from the temporal operating variable curve up to the end of the relevant time period, one or more operating features as statistical or accumulated variables derived from the temporal operating variable curve up to the end of the relevant time period and/or a static operating variable derived from the temporal operating variable curve within the time period.

8. A computer-implemented method for creating a trace graph model for monitoring device batteries of technical devices, the trace graph comprising nodes each having a characteristic operating feature point connected via directed transitions each having a transition probability, at least one of the nodes corresponding to an anomaly node having associated therewith an operating feature point corresponding to a particular failure of device batteries, comprising:
providing a plurality of time-based operating variable curves of a plurality of device batteries;
determining time periods of the operating variable curves using a determination of change point times separating the time periods within each of the operating variable curves;
ascertaining an operating feature point for each of the determined time periods;
grouping the ascertained operating feature points into clusters, each of which is assigned to a node of the trace graph model; and
determining directed transitions between the nodes of the trace graph model, which are each provided with a transition probability from one node to a further node, the transition probabilities determined in each case from an evaluation of frequencies of the transition of a state of the device battery determined by a respective one of the nodes to a respective further state of the device battery determined by a respective one of the nodes.

9. An apparatus configured to carry out the method according to claim 1.

10. A computer program comprising instructions that, when the program is executed by at least one data processing device, prompt the latter to perform the method according to claim 1.

11. A non-transitory machine-readable storage medium comprising commands which, when executed by at least one data processing device, cause the latter to carry out the method according to claim 1.
